(19) United States
(12) Patent Application Publication
(10) Pub. No.: US 2026/0017432 A1
(43) Pub. Date: Jan. 15, 2026

(54) NON-TRANSITORY COMPUTER-READABLE MEDIUM STORING A COMPUTER PROGRAM, INFORMATION PROCESSING METHOD, AND PROCESSING APPARATUS

(71) Applicant: Tokyo Electron Limited, Tokyo (JP)

(72) Inventors: Daiki KAWAHITO, Sapporo City (JP); Daishiro AKIYAMA, Sapporo City (JP); Yusuke OGAWA, Sapporo City (JP); Hironori MOKI, Kurokawa-gun (JP); Takuro TSUTSUI, Sapporo City (JP); Du ZHANG, Albany, NY (US)

(73) Assignee: Tokyo Electron Limited, Tokyo (JP)

(21) Appl. No.: 19/335,245

(22) Filed: Sep. 22, 2025

Related U.S. Application Data
(63) Continuation of application No. PCT/JP2024/011180, filed on Mar. 22, 2024.

(30) Foreign Application Priority Data
Mar. 30, 2023 (JP) 2023-056044

(51) Int. Cl. G06F 30/20

(52) U.S. Cl. CPC G06F 30/20

(57) ABSTRACT

A non-transitory computer-readable medium storing a computer program, an information processing method, and a processing apparatus capable of adjusting flux parameters with high accuracy are provided. A state of plasma is simulated in a processing apparatus comprising a process chamber configured to process a substrate using the plasma. An estimated value of a flux parameter indicating a state where particles originating from the plasma are incident on the substrate is acquired from a simulation result. By using a simulation model that simulates substrate processing using a processing parameter and including the flux parameter, or a trained model that outputs a post-processing shape of the substrate, the processing parameter is adjusted with the acquired estimated value as an initial value of the flux parameter such that the substrate having a specific post-processing shape is obtained from the substrate having a specific initial shape.

### CROSS-REFERENCE TO RELATED APPLICATIONS

This application is a bypass continuation application of international application No. PCT/JP2024/011180 having an international filing date of Mar. 22, 2024, and designating the United States, the international application being based upon and claiming the benefit of priority from Japanese Patent Application No. 2023-056044, filed on Mar. 30, 2023, the entire contents of each are incorporated herein by reference.

### TECHNICAL FIELD

The present disclosure relates to a non-transitory computer-readable medium storing a computer program, an information processing method, and a processing apparatus.

### BACKGROUND

Substrate processing for performing processing such as etching or film formation on a substrate such as a semiconductor wafer or a glass substrate is performed according to a recipe defining processing contents. In related art, a shape simulation is performed using a computer to predict a shape of a substrate obtained by substrate processing. In shape simulation, substrate processing is simulated using a plurality of processing parameters related to the substrate processing according to recipes. Further, a recipe for obtaining a specific substrate is searched for by adjusting processing parameters such that a specific predicted shape can be obtained through the shape simulation. PTL 1 discloses an example of a technique for performing shape simulation.

### CITATION LIST

### Patent Documents

PTL 1: JP6890632B

### SUMMARY

Examples of the substrate processing include processing using plasma, such as plasma etching or chemical vapor deposition (CVD). Flux parameters indicating a state where particles such as ions originating from plasma are incident on a substrate are included in the processing parameters. When the processing parameters are adjusted, the flux parameters are also adjusted.

The present disclosure provides a non-transitory computer-readable medium storing a computer program, an information processing method, and a processing apparatus capable of adjusting flux parameters with high accuracy.

A non-transitory computer-readable medium storing a computer program according to an aspect of the present disclosure causes a computer to execute processing of simulating a state of plasma in a processing apparatus comprising a process chamber configured to process a substrate using the plasma, acquiring, from a simulation result, an estimated value of a flux parameter indicating a state where particles originating from the plasma are incident on a substrate, and by using a simulation model that simulates substrate processing using a processing parameter related to a condition of the substrate processing and including the flux parameter, or a trained model that outputs a post-processing shape of a substrate in accordance with inputs of the processing parameter and an initial shape of the substrate, adjusting the processing parameter with the acquired estimated value as an initial value of the flux parameter such that a substrate having a specific post-processing shape is obtained from a substrate having a specific initial shape.

According to the present disclosure, a non-transitory computer-readable medium storing a computer program, an information processing method, and a processing apparatus capable of adjusting flux parameters with high accuracy can be provided.

### BRIEF DESCRIPTION OF DRAWINGS

FIG. 1 is a conceptual diagram illustrating an example of a configuration of an information processing system according to an embodiment of the disclosure;

FIG. 2 is a block diagram illustrating an example of an internal configuration of an information processing apparatus;

FIG. 3 is a table illustrating an example of a plurality of processing parameters;

FIG. 4 is a conceptual diagram illustrating an example of a configuration of a plasma model;

FIG. 5 is a conceptual diagram illustrating an outline of information processing executed by the information processing apparatus;

FIG. 6 is a flowchart illustrating an example of a procedure of information processing of adjusting processing parameters, which is executed by the information processing apparatus; and

FIG. 7 is a conceptual diagram illustrating an outline of plasma simulation.

FIG. 8 is a diagram of circuitry used to control process operations, such as implementing functions of the information processing apparatus.

### DETAILED DESCRIPTION

Hereinafter, the disclosure will be specifically described with reference to the drawings illustrating an embodiment thereof.

A process for producing a substrate such as a semiconductor wafer, a glass substrate, or a flat panel substrate includes a process of performing processing such as etching or film formation on a substrate. Hereinafter, processing executed on a substrate will be referred to as substrate processing, and an apparatus for executing the substrate processing will be referred to as a processing apparatus. For example, the processing apparatus includes a process chamber, and performs the substrate processing, such as etching, on a substrate disposed in the process chamber. Examples of the substrate processing include processing using plasma, such as plasma etching or chemical vapor deposition (CVD). The processing apparatus processes the substrate in accordance with a predetermined recipe that defines contents of the substrate processing. The substrate processing is performed under processing conditions defined in the recipe. The processing conditions include a shape of the process chamber, a flow rate of the supplied gas, the supplied power, the pressure, and the temperature. In an embodiment of the disclosure, the substrate processing is simulated using processing parameters related to the processing conditions, and processing parameters are adjusted so that a specific predicted shape is obtained.

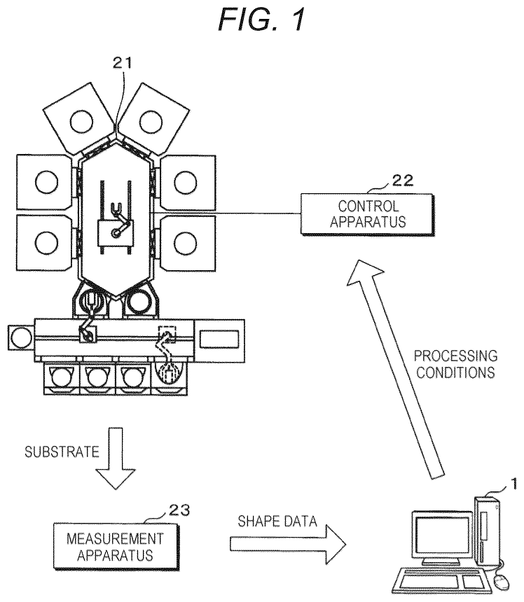

FIG. 1 is a conceptual diagram illustrating an example of a configuration of an information processing system according to an embodiment of the disclosure. The information processing system includes a processing apparatus 21 that executes substrate processing, a control apparatus 22 that controls the processing apparatus 21, a measurement apparatus 23 that measures a shape of the substrate, and an information processing apparatus 1. The processing apparatus 21 performs substrate processing on a substrate. For example, the processing apparatus 21 includes a process chamber, and performs plasma etching as the substrate processing. The control apparatus 22 adjusts a processing condition for the substrate processing executed by processing apparatus 21. The measurement apparatus 23 measures a shape of the substrate before the substrate processing, and a shape of the substrate after the substrate processing is executed by the processing apparatus 21. The measurement apparatus 23 is, for example, a scanning electron microscope or a transmission electron microscope. For example, the substrate is cut, and a cross-sectional shape of the substrate is measured by the measurement apparatus 23. Shape data representing shapes of the substrate before and after the substrate processing is obtained by the measurement apparatus 23.

The information processing apparatus 1 executes an information processing method. The information processing apparatus 1 executes shape simulation using the processing parameters. The information processing apparatus 1 uses the shape data acquired by the measurement apparatus 23 to adjust processing parameters so as to obtain a substrate having a predetermined shape in a shape simulation. The control apparatus 22 can adjust the processing conditions for the substrate processing performed by the processing apparatus 21 in accordance with the adjusted processing parameters.

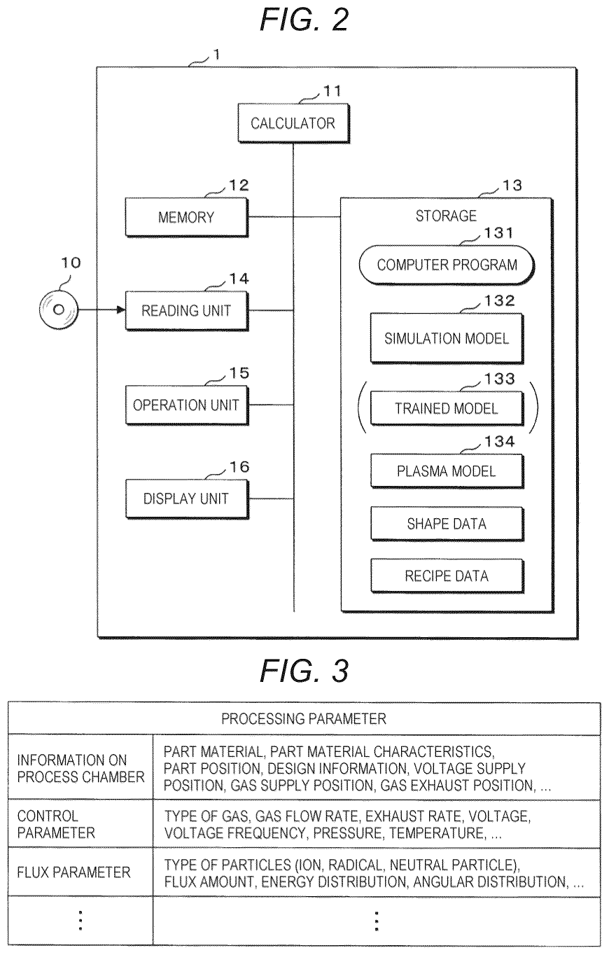

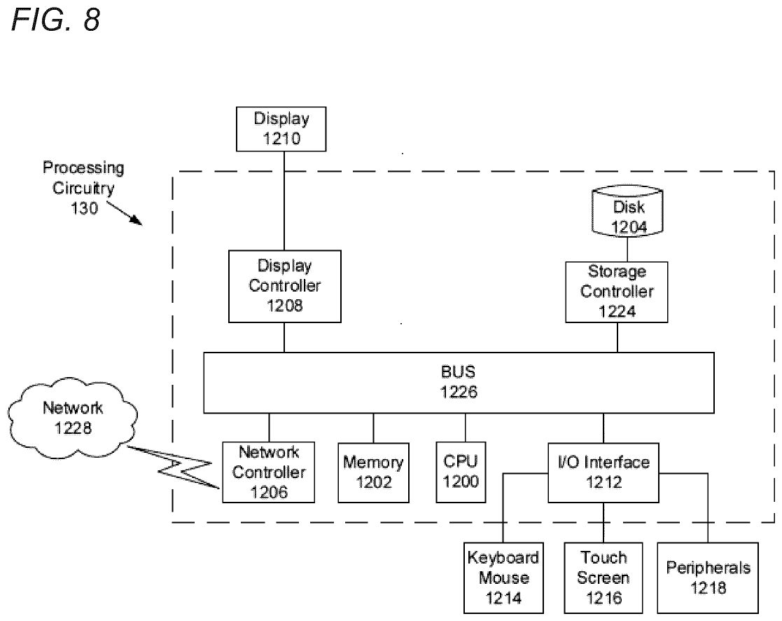

FIG. 2 is a block diagram illustrating an internal configuration example of the information processing apparatus 1. The information processing apparatus 1 is implemented using a computer such as a personal computer or a server apparatus. The information processing apparatus 1 includes a calculator 11, a memory 12, a storage 13, a reading unit 14, an operation unit 15, and a display unit 16. The calculator 11 may be implemented as the processing circuitry 130, discussed later in reference to FIG. 8, and the calculator 11 may be implemented using, for example, a central processing unit (CPU), a graphics processing unit (GPU), or a multi-core CPU. The calculator 11 may also be implemented using a quantum computer. The memory 12 stores temporary data generated along with calculation. The memory 12 is, for example, a random access memory (RAM). The storage 13 is non-volatile, and is, for example, a hard disk or a non-volatile semiconductor memory. The reading unit 14 reads information from a non-transitory computer-readable medium 10 such as a hard disk drive (HDD), a solid-state drive (SSD), an optical disc (e.g., a compact disc (CD) or digital versatile disc (DVD)), or a portable memory (e.g., a USB flash drive). Further, the non-transitory computer-readable medium may comprise all computer-readable medium, with the sole exception being a transitory, propagating signal.

The operation unit 15 receives an input of information such as text by receiving an operation from a user. The operation unit 15 is, for example, a keyboard, a pointing device, or a touch panel. The display unit 16 displays an image. The display unit 16 is, for example, a liquid crystal display or an electroluminescent display (EL display). The operation unit 15 and the display unit 16 may be integrated.

The calculator 11 causes the reading unit 14 to read a computer program (program product) 131 stored in the non-transitory computer-readable medium 10, and causes the storage 13 to store the read computer program 131. The calculator 11 executes processing for implementing functions of the information processing apparatus 1 according to the computer program 131. The computer program 131 may be stored in advance in the storage 13 or may be downloaded from outside the information processing apparatus 1. In this case, the information processing apparatus 1 does not need to be provided with the reading unit 14.

The computer program 131 may be loaded to be executed on a single computer or on a plurality of computers disposed at one site or distributed across a plurality of sites and interconnected by a communication network. That is, the information processing apparatus 1 may be implemented by a plurality of computers, and the computer program 131 may be executed on the plurality of computers connected via the communication network. The information processing apparatus 1 may be implemented using a cloud server.

The information processing apparatus 1 includes a simulation model 132 that performs a shape simulation for predicting a substrate shape obtained by substrate processing. The simulation model 132 simulates substrate processing performed on a substrate having any shape under any processing conditions. The simulation model 132 performs simulation using a plurality of processing parameters related to processing conditions, and calculates a predicted shape obtained by predicting a shape of the substrate after the substrate processing. The simulation model 132 includes a computer program for the shape simulation. The computer program for executing a shape simulation is stored in the storage 13 and included in, for example, the computer program 131.

Alternatively, the information processing apparatus 1 includes a trained model 133 that outputs a predicted shape of the substrate when the shape and processing parameters of the substrate are input, instead of the simulation model 132. The trained model 133 is trained in advance to output the predicted shape when initial shapes, which are shapes of substrates before substrate processing, and processing parameters are input. The trained model 133 is implemented by executing information processing by the calculator 11 in accordance with the computer program 131. For example, the trained model 133 is implemented by using a neural network.

The trained model 133 may be configured with hardware. For example, the trained model 133 may be configured with hardware that includes a processor and a memory storing necessary programs and data. Alternatively, the trained model 133 may be implemented by using a quantum computer. Alternatively, the trained model 133 may be provided outside the information processing apparatus 1, and the information processing apparatus 1 may execute processing using the external trained model 133. For example, the trained model 133 may be implemented using a cloud. The information processing apparatus 1 may include both the simulation model 132 and the trained model 133.

FIG. 3 is a table illustrating an example of a plurality of processing parameters. The plurality of processing parameters include information on the process chamber, control parameters indicating processing conditions in the processing apparatus 21 controlled by the control apparatus 22, and flux parameters indicating the state where particles originating from plasma are incident on the substrate during the substrate processing. The processing parameters may include other pieces of information. The information on the process chamber may include a material of parts that constitute the process chamber, characteristics such as the thermal conductivity or dielectric constant of the part material, and a position of the parts within the process chamber. Further, design information of the process chamber, such as the number of holes for supplying or exhausting a gas, a size of a space to be evacuated, or a shape of the process chamber, may be included. In addition, a voltage supply position, a gas supply position, and a gas exhaust position may be included.

The control parameters may include a type of a gas to be supplied to the process chamber, a flow rate of the gas to be supplied, an exhaust amount of the gas, a plurality of types of voltages supplied to the process chamber, frequencies of the plurality of types of voltages, pressure and a temperature in the process chamber. The flux parameters may include the types of particles, such as ions, radicals, and neutral particles, incident on the substrate, and the flux amount indicating the number of each type of particle incident on the unit area of a surface of the substrate per unit time. Further, the flux parameters may include an energy distribution of each type of particle incident on the surface of the substrate, and a distribution of angles at which each type of particle is incident on the surface of the substrate. In addition, the flux parameters may include the distribution in the surface of the substrate and the temporal changes of the flux amount, the energy distribution, and the angular distribution of each type of particle on the surface of the substrate. The information on the process chamber, the control parameters, and the flux parameters may include other pieces of information.

The plurality of processing parameters may include other parameters. The simulation model 132 and the trained model 133 take a surface reaction of the substrate into consideration, and the processing parameters may include parameters related to the surface reaction. The parameters related to the surface reaction may include an etching probability, which is a probability that the surface of the substrate is etched by particles originating from plasma, and a sputtering probability, which is a probability that the surface of the substrate is sputtered by the particles. The parameters related to the surface reaction may include a deposition probability, which is a probability that the particles deposit on the surface of the substrate, a modification probability, which is a probability that the substance on the surface of the substrate changes due to an interaction with the particles, and a reflection probability, which is a probability that the particles are reflected by the surface of the substrate.

The parameters related to the surface reaction may include an angular distribution of particles desorbed from the surface of the substrate by sputtering, and a sputtering yield, which is an amount of the desorbed substance that depends on the incidence angle of the particles during the sputtering. The parameters related to the surface reaction may include an angular distribution of particles reflected by the surface of the substrate, a defect rate of the surface of the substrate, a temperature change rate of the surface of the substrate, and a particle penetration length, which is the distance that the particles penetrate into the interior of the substrate. The parameters related to the surface reaction may include an amount of electron flux emitted to the substrate and an amount of charge that is charged onto the substrate by incidence of the particles.

The information processing apparatus 1 includes a plasma model 134 that simulates a state of plasma in the processing apparatus 21. The plasma model 134 simulates the state of plasma, such as composition, density, and temperature, based on the information on the process chamber, and the control parameters. The plasma model 134 includes a computer program for simulation. The computer program for the simulation is stored in the storage 13 and included in, for example, the computer program 131.

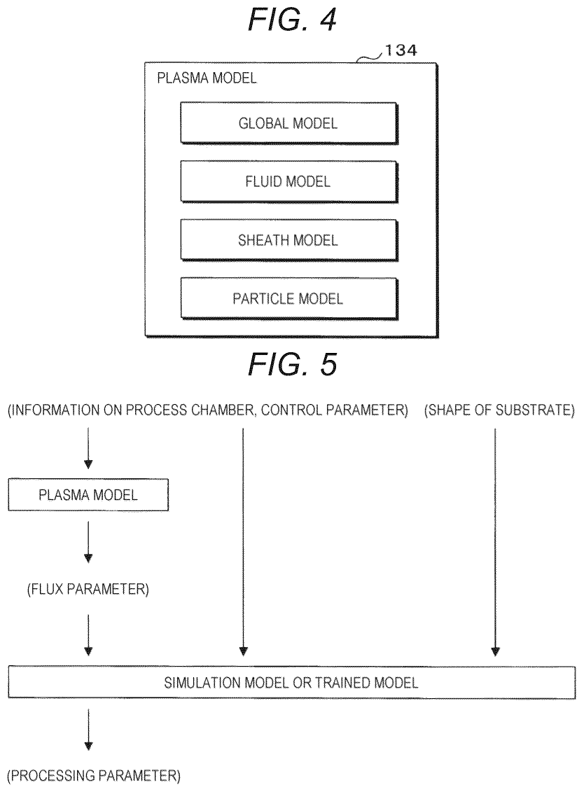

FIG. 4 is a conceptual diagram illustrating an example of a configuration of the plasma model 134. The plasma model 134 includes a global model, a fluid model, a sheath model, and a particle model. The global model is a model that approximates the inside of the process chamber in a zero-dimensional space, and calculates temporal changes in a composition, a density, and a temperature of the plasma. The fluid model is a model that approximates the inside of the process chamber as a fluid divided by a large number of spatial meshes, and calculates spatial distributions and temporal changes in the composition, the density, and the temperature of the plasma. For example, the fluid model includes a model for performing computer aided engineering (CAE) simulation or computational fluid dynamics (CFD) simulation. The sheath model is a model that calculates the flux amount, the energy distribution, and the angular distribution of particles in a vicinity of a wall of the process chamber and in a vicinity of the surface of the substrate, based on the composition, density, and temperature of the plasma.

The particle model is a model that describes behaviors of the particles in the process chamber, calculates a spatial distribution and the temporal changes of the composition, density, and temperature of plasma, and calculates the flux amount, an energy distribution, and an angular distribution of the particles in the vicinity of the wall of the process chamber, and in the vicinity of the surface of the substrate. The flux parameters can be calculated by the processing performed by the global model, the fluid model, and the sheath model. Alternatively, the flux parameters can be calculated by the processing performed by the particle model. The plasma model 134 may include the global model, the fluid model, and the sheath model but not include the particle model, or may include the particle model but not include the global model, the fluid model, or the sheath model.

The storage 13 stores shape data representing the shape of the substrate. The shape data includes data representing the initial shape that is a shape of the substrate before the substrate processing is performed, and data representing the post-processing shape that is a shape of the substrate after the substrate processing. The shape data is, for example, a photograph of a cross-section of the substrate. The shape data is, for example, acquired by the measurement apparatus 23, input into the information processing apparatus 1, and stored in the storage 13. The shape data may be created in the information processing apparatus 1. Further, the storage 13 stores recipe data representing the contents of an existing recipe.

The information processing executed by the information processing apparatus 1 will be described. The information processing apparatus 1 executes information processing to adjust processing parameters such that a specific predicted shape is obtained through shape simulation. FIG. 5 is a conceptual diagram illustrating an outline of the information processing executed by the information processing apparatus 1. The information processing apparatus 1 inputs the information on the process chamber and the control parameters into the plasma model 134, and uses the plasma model 134 to perform plasma simulation for simulating the state of plasma in the processing apparatus 21. The information processing apparatus 1 calculates the flux parameters by the plasma simulation. Next, the information processing apparatus 1 inputs the calculated flux parameters, the information on the process chamber and the control parameters, and the shape of the substrate including the initial shape and the post-processing shape into the simulation model 132 or the trained model 133. The information processing apparatus 1 adjusts the processing parameters using the simulation model 132 or the trained model 133 such that the predicted shape becomes the input post-processing shape, and appropriate processing parameters are acquired.

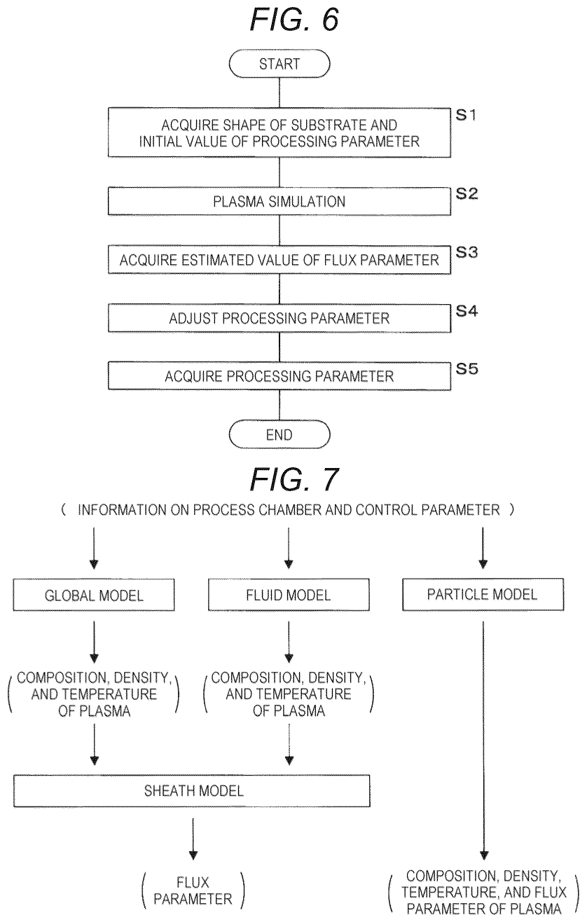

FIG. 6 is a flowchart illustrating an example of a procedure of information processing of adjusting processing parameters, which is executed by the information processing apparatus 1. Hereinafter, the step of the information processing executed by the information processing apparatus 1 will be abbreviated as S. The information processing apparatus 1 executes the following processing by the calculator 11 executing the information processing according to the computer program 131.

Specifically, calculator 11 may be circuitry configured to perform steps S1-S5 and this circuitry may also be a computer or a quantum computer provided with, for example, a processor, a storage, such as memory, an input system, a display, and a signal I/O interface. The calculator 11 including circuitry may be configured by software to perform the steps S1-S5 described herein. In one embodiment, the calculator 11 including circuitry is an Application Specific Integrated Circuit (ASIC) that performs the steps S1-S5, or a hybrid calculator that includes both a programmable calculator, and an ASIC. In this embodiment, the calculator 11 including circuitry is a programmable computer that is configured by software to control individual components of the information processing apparatus 1. The calculator 11 including circuitry allows an operator to input commands to control the information processing apparatus 1 through an input device such as a keyboard, touch panel, or the like. The calculator 11 including circuitry allows display to present the operational state of the information processing apparatus 1 visually. The storage 13 stores control programs. The circuitry including the processor executes the control programs to execute various processes of the information processing apparatus 1, and controls individual components of the information processing apparatus 1.

The information processing apparatus 1 acquires the shape of the substrate and initial values of the processing parameters (S1). In S1, the calculator 11 reads the shape data from the storage 13 to acquire the shape of the substrate that includes the specific initial shape and the specific post-processing shape. Further, the calculator 11 reads the processing parameters from the recipe data to acquire the initial values of the processing parameters. When the initial values of the processing parameters are acquired from the recipe data, plasma simulation based on an existing recipe can be implemented. Based on existing recipes, plasma simulation can be performed under realistic conditions.

The calculator 11 may acquire the shape of the substrate from data other than the shape data, or may acquire the processing parameters from data other than the recipe data. For example, the shape of the substrate or a part of the processing parameters may be input from the outside of the information processing apparatus 1 to the information processing apparatus 1. For example, the user may operate the operation unit 15 to input the shape of the substrate or a part of the processing parameters into the information processing apparatus 1.

The information processing apparatus 1 performs plasma simulation (S2). In S2, the calculator 11 uses the plasma model 134 to simulate the state of plasma generated in the process chamber of the processing apparatus 21 for substrate processing under the information on the process chamber and the control parameters included in the processing parameters. The calculator 11 executes the plasma simulation to calculate flux parameters indicating the state where particles originating from plasma are incident on the substrate in the process chamber.

FIG. 7 is a conceptual diagram illustrating an outline of the plasma simulation. In S2, the calculator 11 inputs the information on the process chamber and the control parameters included in the processing parameters into the global model and the fluid model included in the plasma model 134. The calculator 11 calculates the temporal changes in the composition, density, and temperature of the plasma generated in the process chamber using the global model. Further, the calculator 11 calculates the spatial distribution and the temporal change of the composition, density, and temperature of the plasma using the fluid model.

The calculator 11 inputs the composition, density, and temperature of the plasma calculated using the global model, and the composition, density, and temperature of the plasma calculated using the fluid model, into the sheath model included in the plasma model 134. The calculator 11 calculates the flux amount, the energy distribution, and the angular distribution of the particles in the vicinity of the wall of the process chamber and in the vicinity of the surface of the substrate, using the sheath model. From the calculation results using the sheath model, it is possible to obtain flux parameters including the type of particles incident on the substrate, the flux amount of the particles, and the energy distribution and the angular distribution of the particles incident on the substrate.

Alternatively, the calculator 11 inputs information on the process chamber and the control parameters included in the processing parameters into the particle model included in the plasma model 134. The calculator 11 calculates the spatial distribution and the temporal change of the composition, density, and temperature of the plasma, and the flux amount, the energy distribution, and the angular distribution of the particles in the vicinity of the wall of the process chamber and in the vicinity of the surface of the substrate, using the particle model. From the calculation results using the particle model, it is possible to obtain flux parameters including the type of particles incident on the substrate, the flux amount of the particles, and the energy distribution and angular distribution of the particles incident on the substrate.

The plasma simulation using the particle model can more accurately simulate the state of plasma as compared with the plasma simulation using the global model, the fluid model, and the sheath model. However, the plasma simulation using the global model, the fluid model, and the sheath model can be performed at higher speed as compared with the plasma simulation using the particle model. The calculator 11 may select and execute either the plasma simulation using the global model, the fluid model, and the sheath model, or the plasma simulation using the particle model. The calculator 11 may execute only the plasma simulation using the global model, the fluid model, and the sheath model, or only the plasma simulation using the particle model.

The information processing apparatus 1 acquires an estimated value of the flux parameters (S3). In S3, the calculator 11 uses a value of the flux parameters obtained as a result of the plasma simulation as the estimated value of the flux parameters. The calculator 11 stores the acquired estimated values of the flux parameters in the memory 12 or the storage 13.

In S3, the calculator 11 may acquire the estimated values of flux parameters by integrating the plurality of flux parameters obtained in step S2 into a smaller number of flux parameters. For example, the calculator 11 calculates a statistical value such as an average value or a median value of flux parameters related to a plurality of types of particles to integrate the flux parameters, and uses the calculated statistical value as the estimated value of the flux parameters. For example, the calculator 11 uses a statistical value of flux parameters related to a plurality of types of ions such as argon ions and oxygen ions as an estimated value of flux parameters related to ions. Similarly, the calculator 11 uses a statistical value of flux parameters related to radicals or neutral particles as an estimated value of flux parameters related to radicals or neutral particles. The calculator 11 may integrate the flux parameters related to a plurality of types of particles into a smaller number of flux parameters by other methods such as integrating the flux parameters by valence of ions or radicals.

For example, the calculator 11 calculates a spatial statistical value or a temporal statistical value of the flux parameters to integrate the flux parameters, and uses the spatial statistical value or the temporal statistical value as the estimated value of the flux parameters. For example, the calculator 11 calculates a spatial statistical value of the flux amount, the energy distribution, and the angular distribution of the particles, such as a value obtained by integrating the flux amount, the energy distribution, and the angular distribution in the surface of the substrate. For example, the calculator 11 calculates a time statistical value of the flux amount, the energy distribution, and the angular distribution of the particles, such as a value obtained by integrating the temporal changes of the flux amount, the energy distribution, and the angular distribution. The calculator 11 uses a spatial statistical value or a temporal statistical value of the flux amount, the energy distribution, and the angular distribution of the particles as the estimated value of the flux parameters.

The number of the flux parameters is reduced by integrating the flux parameters.

Accordingly, the number of processing parameters used in subsequent processing is reduced. The subsequent processing may be simplified by reducing the number of processing parameters. Specifically, information processing performed by the simulation model 132 or the trained model 133 using a plurality of processing parameters is simplified, and calculation costs can be reduced.

Next, the information processing apparatus 1 adjusts processing parameters using the simulation model 132 or the trained model 133 (S4). In S4, the calculator 11 executes, by the simulation model 132 using a plurality of processing parameters including flux parameters, shape simulation of performing substrate processing on a substrate having a specific initial shape. The calculator 11 adjusts a plurality of processing parameters by repeating the shape simulation while changing the values of the plurality of processing parameters such that the predicted shape of the substrate calculated by the shape simulation approaches a specific post-processing shape.

The calculator 11 ends the adjustment of the processing parameters in a state where the predicted shape of the substrate calculated by the shape simulation sufficiently approaches the specific post-processing shape. For example, the calculator 11 calculates an error function representing a difference between the predicted shape obtained by the shape simulation and a specific post-processing shape, and ends the adjustment of the processing parameters when a value of the error function falls within the predetermined range.

Alternatively, in S4, the calculator 11 inputs a plurality of processing parameters including the flux parameters and the specific initial shape of the substrate into the trained model 133. The trained model 133 outputs a predicted shape of the substrate in accordance with the input of the processing parameters and the initial shape. The calculator 11 repeats the processing while changing the values of the plurality of processing parameters so that the predicted shape of the substrate output from the trained model 133 approaches a specific post-processing shape. That is, inputting the changed processing parameters and the specific initial shape into the trained model 133 by the calculator 11, and outputting the predicted shape by the trained model 133 are repeated. In this way, the calculator 11 adjusts the plurality of processing parameters.

The calculator 11 ends the adjustment of the processing parameters in a state where the predicted shape of the substrate output from the trained model 133 sufficiently approaches the specific post-processing shape. For example, the calculator 11 calculates an error function representing a difference between the predicted shape output from the trained model 133 and a specific post-processing shape, and ends the adjustment of the processing parameters when the value of the error function falls within the predetermined range.

In S4, the calculator 11 uses the initial values of the processing parameters acquired in S1 as initial values of parameters other than the flux parameters among the plurality of processing parameters. The calculator 11 uses the shapes of the substrate acquired in S1 as the specific initial shape and the specific post-processing shape. The calculator 11 uses the estimated value of the flux parameters acquired in S3 as an initial value of the flux parameters among the plurality of processing parameters. The initial value of this flux parameter may be expected to be close to the value of the optimal flux parameter. Therefore, the calculator 11 can adjust the flux parameter to an appropriate value with a high probability.

Further, when adjusting the value of the flux parameters, the calculator 11 adjusts the flux parameters within a limited specific range that includes the initial value. For example, the calculator 11 sets a predetermined value as a positive value, and sets a range from (initial value—predetermined value) to (initial value+predetermined value) as a specific range. For example, the calculator 11 sets a range from the value obtained by decreasing the initial value by a predetermined proportion to the value obtained by increasing the initial value by a predetermined proportion, as a specific range. For example, the predetermined proportion is 20%. The information for defining the specific range is stored in advance in the storage 13. The specific range may be input into the information processing apparatus 1 by the user operating the operation unit 15. It is highly probable that the value of the optimal flux parameter is included in the specific range that includes the initial value. Therefore, the calculator 11 can efficiently adjust the flux parameter to an appropriate value, as compared with the case of comprehensively searching for the flux parameter from a wide range.

Next, the information processing apparatus 1 acquires the plurality of adjusted processing parameters (S5). In S5, the calculator 11 acquires the final processing parameters adjusted in S4. The obtained processing parameters correspond to processing conditions suitable for the substrate processing for obtaining a substrate having a specific post-processing shape from a substrate having a specific initial shape. The information processing apparatus 1 may display the plurality of acquired processing parameters on the display unit 16. The information processing apparatus 1 may set the processing conditions for the substrate in the processing apparatus 21 in accordance with the plurality of acquired processing parameters. After S5 is ended, the information processing apparatus 1 ends the information processing of adjusting the processing parameters.

As described in detail above, in an embodiment of the disclosure, the information processing apparatus 1 acquires the estimated value of the flux parameters by the plasma simulation, and adjusts the processing parameters including the flux parameters by using the simulation model 132 or the trained model 133. Before adjusting the processing parameters, an estimated value of the flux parameter close to an optimum value is obtained through the plasma simulation. The deviation between the value of the adjusted flux parameter and the optimal value is reduced by setting the obtained estimated value to the initial value. Therefore, the flux parameter can be adjusted with higher accuracy than in the related art in which the flux parameter is comprehensively searched for from a wide range.

The present embodiment was compared with the related art. In each processing, a Loss value, which is an output value of a loss function for calculating the deviation between a predicted shape obtained by using the adjusted processing parameters and a specific post-processing shape, was acquired. Further, the processing of S1 to S5 according to the present embodiment was performed a plurality of times, and the Loss value was acquired in each processing. Further, the range of deviation of the Loss value obtained in the present embodiment was sufficiently smaller than the range of deviation of the Loss value obtained in the related art. In the present embodiment, the processing parameters are adjusted with high accuracy.

Further, the value of the parameter related to the surface reaction included in the processing parameters acquired through the processing of S1 to S5 was close to the value of the parameter related to the actual surface reaction obtained in the actual substrate processing in the processing apparatus 21. In this way, in an embodiment of the disclosure, the processing parameters including the flux parameters can be adjusted with high accuracy by adjusting the flux parameters with high accuracy.

FIG. 8 is a block diagram of processing circuitry 130 for performing computer-based operations described herein. FIG. 8 illustrates processing circuitry 130 that may be used to control any computer-based control processes, descriptions or blocks in flowcharts can be understood as representing modules, segments or portions of code which include one or more executable instructions for implementing specific logical functions or steps in the process, and alternate implementations are included within the scope of the exemplary embodiments of the present advancements in which functions can be executed out of order from that shown or discussed, including substantially concurrently or in reverse order, depending upon the functionality involved, as would be understood by those skilled in the art. The various elements, features, and processes described herein may be used independently of one another or may be combined in various ways. All possible combinations and sub-combinations are intended to fall within the scope of this disclosure.

In FIG. 8, the processing circuitry 130 includes a CPU 1200 which performs one or more of the control processes described above/below. The process data and instructions may be stored in memory 1202. These processes and instructions may also be stored on a storage medium disk 1204 such as a hard drive (HDD) or portable storage medium or may be stored remotely. Further, the claimed advancements are not limited by the form of the computer-readable media on which the instructions of the inventive process are stored. For example, the instructions may be stored on CDs, DVDs, in FLASH memory, RAM, ROM, PROM, EPROM, EEPROM, hard disk or any other information processing device with which the processing circuitry 130 communicates, such as a server or computer.

Further, the claimed advancements may be provided as a utility application, background daemon, or component of an operating system, or combination thereof, executing in conjunction with CPU 1200 and an operating system such as Microsoft Windows, UNIX, Solaris, LINUX, Apple MAC-OS and other systems known to those skilled in the art.

The hardware elements in order to achieve the processing circuitry 130 may be realized by various circuitry elements. Further, each of the functions of the above described embodiments may be implemented by circuitry, which includes one or more processing circuits. A processing circuit includes a particularly programmed processor, for example, processor (CPU) 1200, as shown in FIG. 8. A processing circuit also includes devices such as an application specific integrated circuit (ASIC) and conventional circuit components arranged to perform the recited functions.

In FIG. 8, the processing circuitry 130 includes a CPU 1200 which performs the processes described above. The processing circuitry 130 may be a general-purpose computer or a particular, special-purpose machine.

Alternatively, or additionally, the CPU 1200 may be implemented on an FPGA, ASIC, PLD or using discrete logic circuits, as one of ordinary skill in the art would recognize. Further, CPU 1200 may be implemented as multiple processors cooperatively working in parallel to perform the instructions of the inventive processes described above.

The processing circuitry 130 in FIG. 8 also includes a network controller 1206, such as an Intel Ethernet PRO network interface card from Intel Corporation of America, for interfacing with network 1228. As can be appreciated, the network 1228 can be a public network, such as the Internet, or a private network such as an LAN or WAN network, or any combination thereof and can also include PSTN or ISDN sub-networks. The network 1228 can also be wired, such as an Ethernet network, or can be wireless such as a cellular network including EDGE, 3G and 4G wireless cellular systems. The wireless network can also be Wi-Fi, Bluetooth, or any other wireless form of communication that is known.

The processing circuitry 130 further includes a display controller 1208, such as a graphics card or graphics adaptor for interfacing with display 1210, such as a monitor. A general purpose I/O interface 1212 interfaces with a keyboard and/or mouse 1214 as well as a touch screen panel 1216 on or separate from display 1210. General purpose I/O interface also connects to a variety of peripherals 1218 including printers and scanners.

The general-purpose storage controller 1224 connects the storage medium disk 1204 with communication bus 1226, which may be an ISA, EISA, VESA, PCI, or similar, for interconnecting all of the components of the processing circuitry 130. A description of the general features and functionality of the display 1210, keyboard and/or mouse 1214, as well as the display controller 1208, storage controller 1224, network controller 1206, sound controller 1220, and general purpose I/O interface 1212 is omitted herein for brevity as these features are known.

The exemplary circuit elements described in the context of the present disclosure may be replaced with other elements and structured differently than the examples provided herein. Moreover, circuitry configured to perform features described herein may be implemented in multiple circuit units (e.g., chips), or the features may be combined in circuitry on a single chipset.

The functions and features described herein may also be executed by various distributed components of a system. For example, one or more processors may execute these system functions, wherein the processors are distributed across multiple components communicating in a network. The distributed components may include one or more client and server machines, which may share processing, in addition to various human interface and communication devices (e.g., display monitors, smart phones, tablets, personal digital assistants (PDAs)). The network may be a private network, such as a LAN or WAN, or may be a public network, such as the Internet. Input to the system may be received via direct user input and received remotely either in real-time or as a batch process. Additionally, some implementations may be performed on modules or hardware not identical to those described. Accordingly, other implementations are within the scope that may be claimed.

Having now described embodiments of the disclosed subject matter, it should be apparent to those skilled in the art that the foregoing is merely illustrative and not limiting, having been presented by way of example only. Thus, although particular configurations have been discussed herein, other configurations can also be employed. Numerous modifications and other embodiments (e.g., combinations, rearrangements, etc.) are enabled by the present disclosure and are within the scope of one of ordinary skill in the art and are contemplated as falling within the scope of the disclosed subject matter and any equivalents thereto. Features of the disclosed embodiments can be combined, rearranged, omitted, etc., within the scope of the disclosure to produce additional embodiments. Furthermore, certain features may sometimes be used to advantage without a corresponding use of other features. Accordingly, Applicant(s) intend(s) to embrace all such alternatives, modifications, equivalents, and variations that are within the spirit and scope of the disclosed subject matter.

The disclosure is not limited to contents of the above-described embodiment, and various modifications may be made within the scope described in the following claims. In other words, embodiments obtained by combining technical means appropriately changed within the scope indicated in the claims are also included in the technical scope of the disclosure.

The features described in each embodiment can be combined with each other. In addition, the independent and dependent claims set forth in the claims can be combined with each other in any and all combinations, regardless of the reciting format. Furthermore, the claims use a format of describing claims that recite two or more other claims (multi-claim format). However, the present disclosure is not limited thereto. The claims may also be described using a format of multi-claims reciting at least one multi-claim (multi-multi claims).

1. A non-transitory computer-readable medium storing a computer program for causing a computer to execute processing of:
simulating a state of plasma in a processing apparatus comprising a process chamber configured to process a substrate using the plasma,
acquiring, from a simulation result, an estimated value of a flux parameter indicating a state where particles originating from the plasma are incident on the substrate, and
by using a simulation model that simulates substrate processing using a processing parameter related to a condition of the substrate processing and including the flux parameter, or a trained model that outputs a post-processing shape of the substrate in accordance with inputs of the processing parameter and an initial shape of the substrate, adjusting the processing parameter with the acquired estimated value as an initial value of the flux parameter such that the substrate having a specific post-processing shape is obtained from the substrate having a specific initial shape.

2. The non-transitory computer-readable medium storing the computer program according to claim 1, wherein
the computer is caused to execute processing of simulating the state of plasma by simulation using a global model, a fluid model, and a sheath model, or simulation using a particle model.

3. The non-transitory computer-readable medium storing the computer program according to claim 1, wherein
the computer is caused to execute processing of simulating the state of plasma based on an existing recipe that defines processing contents for the substrate.

4. The non-transitory computer-readable medium storing the computer program according to claim 1, wherein
the computer is caused to execute processing of
acquiring states of a plurality of types of particles, or a spatial distribution or a temporal change of the states of the particles by simulation of the state of plasma, and
acquiring, as the estimated value of the flux parameter, a statistical value of parameters indicating the states of the plurality of types of particles, or a spatial statistical value or a temporal statistical value of parameters indicating the states of the particles.

5. The non-transitory computer-readable medium storing the computer program according to claim 1, wherein
the computer is caused to execute processing of adjusting the flux parameter in a specific range based on the estimated value when adjusting the processing parameter.

6. The non-transitory computer-readable medium storing the computer program according to claim 1, wherein
the flux parameter includes a type, a flux amount, an energy distribution, or an angular distribution of particles incident on the substrate.

7. The non-transitory computer-readable medium storing the computer program according to claim 1, the computer program causing the computer to execute processing of:
calculating an error function representing a difference between a predicted shape of the substrate and the specific post-processing shape, and ending the adjustment of the processing parameters when an error value of the error function is within a predetermined range.

8. The non-transitory computer-readable medium storing the computer program according to claim 1, the computer program causing the computer to execute processing of:
integrating multiple flux parameters obtained from the plasma state simulation into a smaller number of parameters to obtain the estimated value.

9. An information processing method comprising:
simulating a state of plasma in a processing apparatus comprising a process chamber configured to process a substrate using the plasma,
acquiring an estimated value of a flux parameter indicating a state where particles originating from the plasma are incident on the substrate from a simulation result, and
by using a simulation model that simulates substrate processing using a processing parameter related to a condition of the substrate processing and including the flux para meter, or a trained model that outputs a post-processing shape of the substrate in accordance with inputs of the processing parameter and an initial shape of the substrate, adjusting the processing parameter with the acquired estimated value as an initial value of the flux parameter such that the substrate having a specific post-processing shape is obtained from the substrate having a specific initial shape.

10. The information processing method according to claim 9, further comprising:
simulating the state of the plasma by simulation using a global model, a fluid model, and a sheath model, or simulation using a particle model.

11. The information processing method according to claim 9, further comprising:
simulating that state of the plasma based on an existing recipe that defines processing contents for the substrate.

12. The information processing method according to claim 9, further comprising:
acquiring states of a plurality of types of particles, or a spatial distribution or a temporal change of the states of the particles by simulation of the state of plasma, and
acquiring, as the estimated value of the flux parameter, a statistical value of parameters indicating the states of the plurality of types of particles, or a spatial statistical value or a temporal statistical value of parameters indicating the states of the particles.

13. The information processing method according to claim 9, further comprising:
adjusting the flux parameter in a specific range based on the estimated value when adjusting the processing parameter.

14. The information processing method according to claim 9, further comprising:
the flux parameter includes a type, a flux amount, an energy distribution, or an angular distribution of particles incident on the substrate.

15. The information processing method according to claim 9, further comprising:
calculating an error function representing a difference between a predicted shape of the substrate and the specific post-processing shape, and ending the adjustment of the processing parameters when an error value of the error function is within a predetermined range.

16. The information processing method according to claim 9, further comprising:
integrating multiple flux parameters obtained from the plasma state simulation into a smaller number of parameters to obtain the estimated value.

17. A processing apparatus comprising:
a process chamber for substrate processing of a substrate; and
circuitry configured to
simulate a state of plasma in the processing apparatus to process the substrate using the plasma,
acquire an estimated value of a flux parameter indicating a state where particles originating from the plasma are incident on the substrate from a simulation result,
by using a simulation model that simulates the substrate processing using a processing parameter related to a condition of the substrate processing and including the flux parameter, or a trained model that outputs a post-processing shape of the substrate in accordance with inputs of the processing parameter and an initial shape of the substrate, adjust the processing parameter with the acquired estimated value as an initial value of the flux parameter such that the substrate having a specific post-processing shape is obtained from the substrate having a specific initial shape, and
control the processing apparatus to process the substrate using the plasma using the adjusted processing parameter.

18. The processing apparatus according to claim 17, wherein
the circuitry is further configured to simulate the state of plasma by simulation using a global model, a fluid model, and a sheath model, or simulation using a particle model.

19. The processing apparatus according to claim 17, wherein
the circuitry is further configured to calculate an error function representing a difference between a predicted shape of the substrate and the specific post-processing shape, and ending the adjustment of the processing parameters when an error value of the error function is within a predetermined range.

20. The processing apparatus according to claim 17, wherein
the circuitry is further configured to integrate multiple flux parameters obtained from the plasma state simulation into a smaller number of parameters to obtain the estimated value.
